(19) United States
(12) Patent Application Publication
(10) Pub. No.: US 2007/0263425 A1
(43) Pub. Date: Nov. 15, 2007

(54) MEMORY ARRANGEMENT

(75) Inventor: Hermann Ruckerbauer, Moos (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/672,778

(22) Filed: Feb. 8, 2007

(30) Foreign Application Priority Data
Feb. 8, 2006 (DE) 10 2006 005 798.8

(51) Int. Cl. G11C 11/24; G11C 7/10

(52) U.S. Cl. 365/149; 365/189.01; 365/189.08; 365/220

(57) ABSTRACT

A memory arrangement is disclosed. In one embodiment, the control device includes a plurality of memory arrays for storing data and a control device for controlling the transfer of data between the plurality of memory arrays and external circuits. In one embodiment, the control device is arranged on a different semiconductor chip than the plurality of memory arrays. The plurality of memory arrays is arranged symmetrically in a plurality of stacks and the control device is arranged in a central arrangement with respect to the stacks.

### CROSS-REFERENCE TO RELATED APPLICATIONS

This Utility Patent Application claims priority to German Patent Application No. DE 10 2006 005 798.8 filed on Feb. 8, 2006, which is incorporated herein by reference.

### BACKGROUND

The present invention relates to a memory arrangement.

There is an ongoing demand for higher memory capacities in computer systems. Due to structural limitations it is not always possible to add further memory modules to increase memory capacity. Therefore a trend exists to increase the capacity of a memory module. One possible way is to increase the capacity of memory chips or memory arrangements. Problems arise with regard to speed and signal integrity because of the higher density.

Accordingly, there is a need for improved memory arrangements that address these and other shortcomings of the current art.

For these and other reasons, there is a need for the present invention.

### SUMMARY

One embodiment provides a memory arrangement having a plurality of memory arrays for storing data and a control device configured to control the transfer of data between the plurality of memory arrays and external circuits. The control device is arranged on a different semiconductor chip than the plurality of memory arrays. The plurality of memory arrays is arranged symmetrically in a plurality of stacks. The control device is arranged in a central arrangement with respect to the stacks.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a schematic illustration of an embodiment of a memory arrangement together with an external memory controller.

FIG. 2 illustrates an embodiment of a memory arrangement, the memory arrays being arranged in two stacks in a manner offset one above another.

FIG. 3 illustrates another embodiment of a memory arrangement, wherein the memory arrays are arranged in four stacks in a manner offset one above another.

FIG. 4 illustrates a further embodiment of a memory arrangement, wherein the control device is arranged on another side of the circuit board than the memory arrays.

FIG. 5 illustrates a memory module including a plurality of memory arrangements.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention relates to a memory arrangement, in which a control device and a memory array of the memory arrangement are arranged separately from one another.

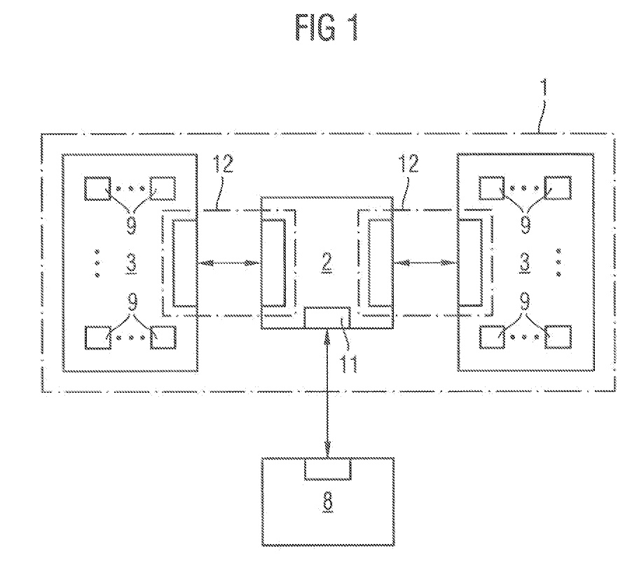

FIG. 1 illustrates one embodiment of a memory arrangement 1 together with an external memory controller 8. The memory arrangement 1 includes a control device 2 and two memory arrays 3. The memory arrangement 1 is connected to the external memory controller 8 via a first interface 11 realized in the control device 2. Each of the two memory arrays 3 is connected to the control device 2 via a respective second interface 12. The two memory arrays 3 include an equal number of memory cells 9 in which the data to be stored by the memory arrangement 1 are stored.

This exemplary memory arrangement includes a control device 2 or a spine for controlling the transfer of data between the memory arrays 3 and a memory controller 8 arranged outside the memory arrangement. In this embodiment, the control device 2 is arranged on a dedicated semiconductor chip, on which the memory arrays are not arranged.

By arranging the control device 2 and the memory arrays on different semiconductor chips, it is possible to produce the control device 2 by a development process for high-speed circuits, for example with a plurality of metal layers for improving performance, while the memory arrays can be fabricated by the production process which is customary for a conventional memory arrangement, for example a DRAM, and which could be orientated in particular to a low leakage current. As a result, the control device 2 can operate at a high speed, while the memory arrays could operate at a slower speed customary for a conventional memory arrangement.

In this embodiment, the control device 2 has a first interface 11 via which a signal exchange between the memory arrangement 1 and the memory controller 8 arranged outside the memory arrangement takes place. Furthermore, the memory arrangement 1 includes second interfaces 12, via which the memory arrays 3 are connected to the control device 2. The clock frequency at which the first interface 11 operates can be at least a factor of 2 greater than the clock frequency at which the second interfaces 12 operate. Furthermore, the control device 2 can serialize data which it receives via the second interfaces 12 and outputs via the first interface 11, and parallelize data which it receives via the first interface 11 and outputs via the second interfaces 12.

Since the memory arrangement 1 is connected to the outside world (e.g., a host system) by the first interface 11, which is arranged within the control device 2 in this embodiment, the clock frequency of the first interface 11 prescribes the clock frequency at which the memory arrangement 1 is operated as viewed externally. Since the clock frequency is at least a factor of 2 greater than the clock frequency of the second interfaces 12, it is possible to operate the memory arrangement 1 with external circuits at a higher clock rate than is the case with comparable conventional memory arrangements, in which the control device and the memory arrays are not separated and which therefore must operate at a slower clock frequency.

Since the control device 2 can parallelize data which are fed into the memory arrangement 1 externally towards the memory arrays, and conversely serializes data which are output from the memory arrays towards the outside, the memory arrangement 1 can operate with external circuits at a higher clock frequency or speed than the memory arrays operate. To put it another way, data which reach the memory arrangement 1 externally via a small number of lines via the first interface can be distributed by the control device 2 between a plurality of lines which are connected to the memory arrays.

The second interface 12 may be configured to be not addressable externally and may be further configured in any desired format, for example in accordance with the EDO (extended data out) interface description.

Since a data exchange between the memory arrangement 1 and external circuits takes place via the first interface 11, the first interface 11 is standardized. In this embodiment, the first interface 11 may for example fulfil one of the following interface definitions: DDR2, DDR3, DDRX. To fulfil a new interface definition, it is only necessary for the first interface 11 and thus the control device 2 to be correspondingly changed, while the second interface 12, which regulates the data exchange between the control device 2 and the memory arrays 3, can remain unaffected by such a change.

The individual memory arrays may in each case be formed on a dedicated semiconductor chip. If a ratio between a number of test specimens tested as OK and a number of test specimens tested overall is compared, this ratio is higher for memory arrays which are in each case formed on a dedicated semiconductor chip than for memory arrangements produced conventionally on a single semiconductor chip. The reason for this is that given an identical defect frequency per silicon area, the defect frequency is greater, the greater the silicon area required by a test specimen. Since the silicon area required by an individual memory array according to the embodiment is relatively small in relation to a silicon area occupied by a memory arrangement produced conventionally on one semiconductor chip, the ratio described above is also higher in the case of the memory arrays according to the embodiment. This means that the yield per wafer is higher in the case of the memory arrangements according to the embodiment than in the case of conventional memory arrangements.

The control device 2 may include an addressing logic for addressing the corresponding memory cells of the memory arrangement 1, a command decoding device for decoding commands or instructions or converting them into internal command or instruction sequences, a refresh logic for periodically refreshing the memory content of the memory cells, and a supply voltage generating device for supplying all parts of the memory arrangement, including the memory arrays, with voltage.

The control device 2 could further contain buffering means to buffer data, commands and addresses and clock signals which are transferred to and from the memory arrays 3. Either a single one of the aforementioned buffer types could implemented or any combination of the types.

Each memory array 3 may include at least one word line, with which a row of memory cells of the respective memory array is selected, at least one bit line, which carries the information of or for the corresponding memory cell, an address decoding, by which a memory address is decoded or converted into an internal signal allocation, a sense amplifier, by which the information read from the memory cells is amplified, and an address selection.

The first interface 11 may include output drivers for amplifying the signals transmitted towards the outside, an ESD protection device for affording protection against over voltages, and a command decoding device.

The first interface 11 can be adapted to various external circuits. These encompass for example memory controllers, CPUs or GPUs, buffer chips, e.g., of a fully buffered DIMM, or other memory arrangements.

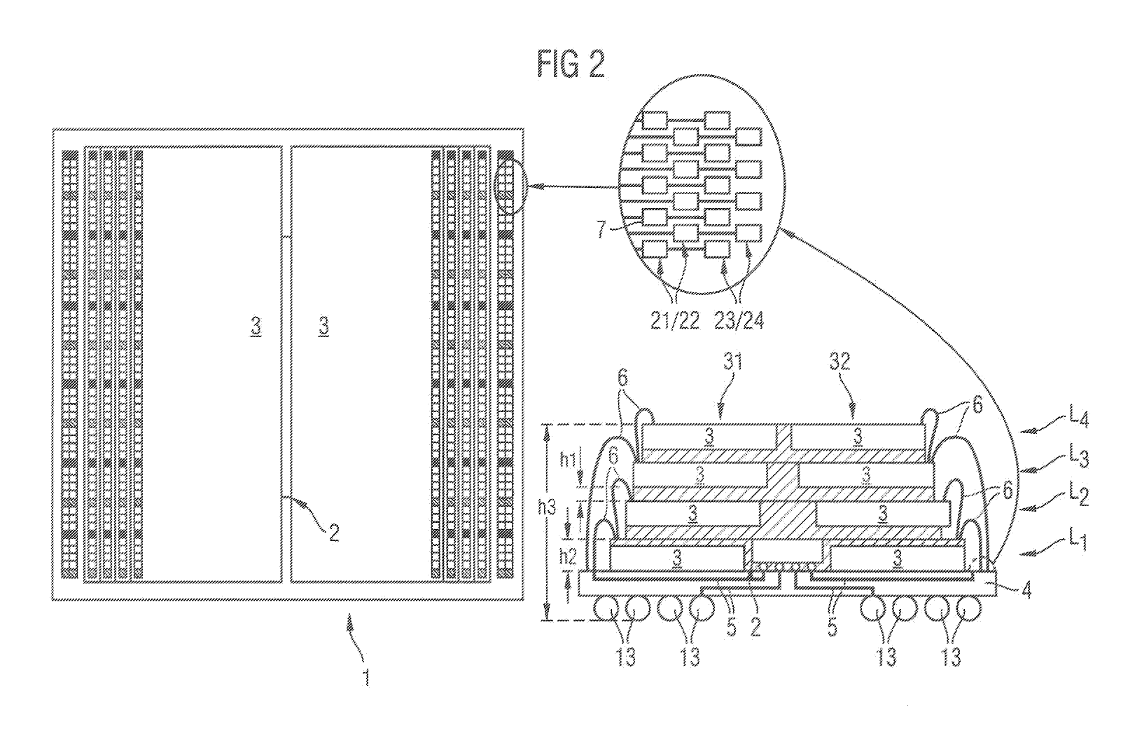

FIG. 2 illustrates a further embodiment of a memory arrangement. This memory arrangement 1 includes a left-hand stack 31 and a right-hand stack 32, each of the stacks 31, 32 having four memory arrays 3 arranged one above another in a manner offset with respect to one another. In this embodiment, the memory arrays 3 are arranged one above another by die stacking.

Between the two stacks 31, 32, the single control device 2 of the memory arrangement 1 is arranged in a first layer L1 of the memory arrangement 1 approximately at the level of the bottommost memory array 3 of the two stacks 31, 32. The control device 2 is applied on a printed circuit board 4, e.g., by a flip-chip technique.

Via conductor tracks 5 in the printed circuit board 4, the control device 2 is connected to contacts 13, on the one hand, and to pads 7 on the other hand, which are arranged at the left-hand and right-hand edges of the printed circuit board 4 in each case alongside the memory arrays 3 of the first and second stacks 31, 32 arranged in the bottommost layer L1. A connection between the memory arrangement 1 and circuits 8 arranged outside the memory arrangement 1 is realized via the contacts 13. By contrast, a connection between the memory controller 2 and the memory arrays 3 is realized via the pads 7. In this case, the memory controller 2 is connected to a plurality of pads in each case both on the left-hand side and on the right-hand side of the printed circuit board 4, each of the pads in turn being connected to a further pad via a conductor track, as is illustrated at the top by the ellipse in FIG. 2. The pad series designated by the reference symbols 21 and 22 in the ellipse are connected per pad in each case via a bonding wire (total of 9 bonding wires for the pads in the ellipse) to pads of the first memory array 3 in the layer L1 of the right-hand stack 32. These pads of the first memory array 3 in the right-hand stack 32 are in turn connected via nine bonding wires to 9 pads of the second memory array 3 in the second layer L2 of the right-hand stack 32. In a similar manner, the nine pads of the pad series designated by the reference symbols 23 and 24 are connected via nine bonding wires to the corresponding pads of the third memory array of the right-hand stack 32 in the third layer L3. These nine pads of the third memory array 3 are in turn connected via 9 bonding wires to nine pads of the fourth memory array of the right-hand stack 32 in the fourth layer L4. Consequently, terminals of the control device 2 are connected in parallel to the respective pads of the four memory arrays of the right-hand stack 32.

Since the pads of the memory arrays 3 are situated at the edge, an RDL is not required.

As can be seen in FIG. 2, the four memory arrays 3 of the left-hand stack 31 are connected to the control device 2 in the same way. That is to say, that it holds true for the left-hand stack 31, too, that terminals of the control device 2 are connected in parallel to the respective pads of the four memory arrays of the left-hand stack 31.

Since the pads 7 of the memory arrays 3 are each arranged at the edge and since the memory arrays 3 are arranged one above another in an offset manner in such a way that the space above the pads of the memory arrays 3 is uncovered, the memory arrays 3 can be arranged very closely one above another. That is to say that a height h1 between the second memory array 3 of the layer L2 and the third memory array 3 of the layer L3 can be kept significantly smaller in comparison with conventional memory arrangements. The height h1 also occurs between the third memory array 3 in the third layer L3 and the fourth memory array 3 in the fourth layer L4. By contrast, a distance between the first memory array and the second memory array in the second layer L2 is chosen to be greater than the height h1, since here the distance between the control device 2 and the memory array in the second layer L2 prescribes the distance between the first memory array and the second memory array. To summarize, a total height h3 of the memory arrangement 1, measured from the lower edge of the contacts 13 up to the upper edge of the respective fourth memory array, is significantly smaller on account of the small distances between the memory arrays than in the case of a conventional memory arrangement, in which, by way of example four DRAMs are arranged one above another.

By virtue of the memory arrays 3 of the left-hand and right-hand stacks 31, 32 in each case being arranged one above another in a manner offset inwardly, the space present above the control device 2 is also utilized virtually optimally, with the result that the width dimensions of the memory arrangement 1 are also virtually minimal.

On the left in FIG. 2, the memory arrangement 1 is illustrated as viewed from above. This reveals on the left the topmost or fourth memory array 3 (layer L4) of the left-hand stack 31 and on the right the topmost or fourth memory array 3 of the right-hand stack 32. Part of the top side of the control device 2 can be discerned in the centre between the two memory arrays. A pad double series is in each case illustrated on the far right and on the far left, in which case the pads on the printed circuit board 4 are intended to be illustrated schematically, a detail of these pads likewise being illustrated in the ellipse at the top in FIG. 2. Alongside the two pad double series at the left-hand and right-hand edges of the memory arrangement 1, four pad series are arranged alongside one another in each case as viewed inwardly. In this case, the respective outermost one of these four pad series is the pad series of the respective first memory array in the layer L1, the next pad series arranged alongside that as viewed inwardly is the pad series of the respective second memory array 3 in the layer L2, the next pad series as viewed inwardly alongside there is the pad series of the respective third memory array 3 in the layer L3, and the two innermost pad series are the pad series of the fourth memory array of the left-hand and right-hand stacks 31, 32 in the layer L4. The pad series of a memory array 3 in this case contains the corresponding pads 7 of the memory array 3.

It can clearly be discerned on the left in FIG. 2 that the space above the pads 7 of the individual memory arrays 3 is sufficiently free, so that the individual pads 7 can be connected well by bonding wires 6 using a simple bonding method.

Each of the memory arrays 3 could be a memory bank of the memory arrangement 1. In this case, a memory bank contains all the memory cells in which data of a specific contiguous address range of the memory arrangement are stored, that is to say that mutually independent memory areas of the memory arrangement 1 are stored in each memory bank.

In one embodiment, all the memory arrays have identical dimensions and an identical number of memory cells in which the data to be stored by the memory arrangement 1 are stored.

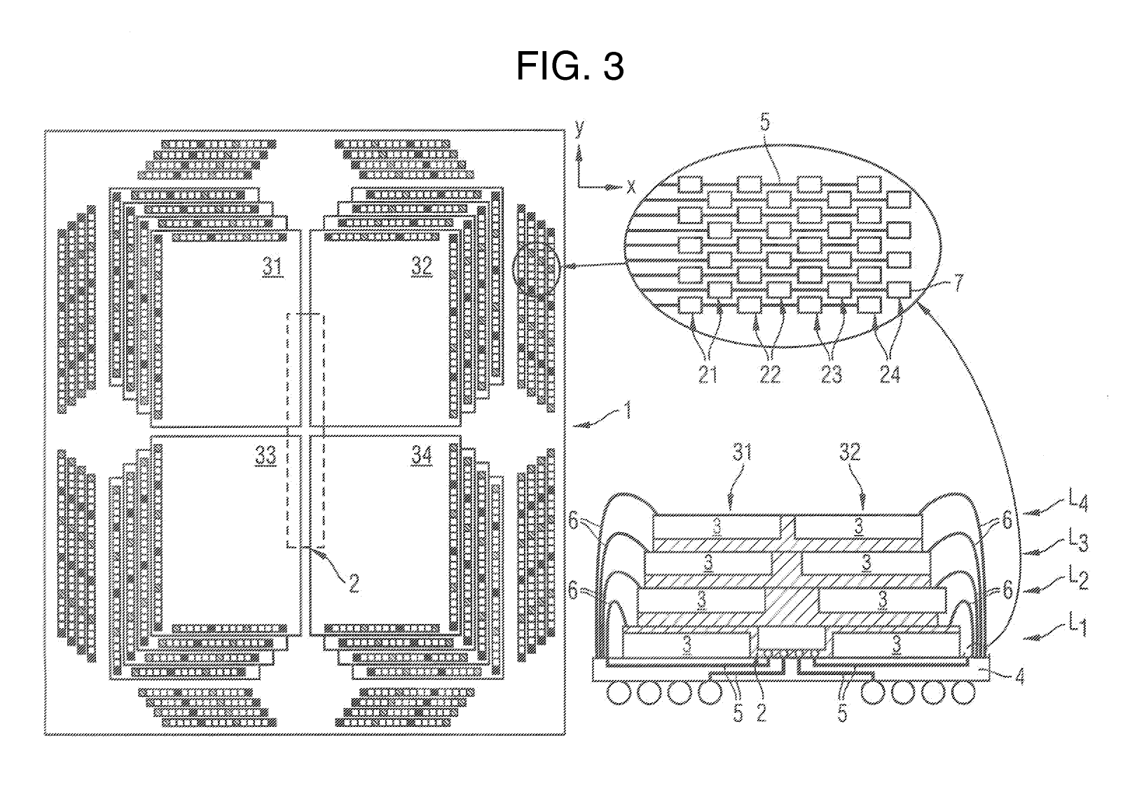

FIG. 3 illustrates a further embodiment of a memory arrangement. This memory arrangement 1 includes four stacks 31-34 each of four memory arrays 3. These four stacks 31-34 are arranged at the four corners of a rectangle, as is illustrated in the left-hand part of FIG. 3. The single control device 2 is arranged centrally with respect to the four stacks 31-34. Since the memory arrangement 1 of FIG. 3 corresponds in many details to the memory arrangements 1 illustrated in FIG. 2, only the differences with respect to the embodiment discussed previously are described below.

The control device 2 is connected to all four edges of the memory arrangement 1 via conductor tracks 5 in the printed circuit board, as illustrated in the left-hand part of FIG. 3. In this embodiment, at the respective two uncovered edges of each stack 31-34, in each case four pad series are arranged on the printed circuit board 4, as can be discerned in the left-hand part of FIG. 3. In total, therefore, for the four stacks 31-34 in each case two times four pad series, that is to say a total of 32 pad series, are present on the printed circuit board 4. By bonding wires 6, each pad 7 of such a pad series is connected to a pad at the edge of a memory array 3 of a stack 31-34 as is illustrated in the bottom right part of FIG. 3. The memory arrays 3 of a stack 31-34 are arranged in an offset manner with respect to a memory array 3 arranged thereabove both in the x direction and in the y direction in such a way that the pads at the edge of the respective memory array 3 which are arranged in each case towards the edge of the memory arrangement 1 are freely accessible from above, that is to say are not covered by memory arrays 3 arranged thereabove. As a result, all pads of the 16 memory arrays can be connected with bonding wires even when two memory arrays 3 arranged one above another are arranged one above another with an arbitrarily small distance. In other words, the distance between two memory arrays 3 arranged one above another is not prescribed by the bonding method. Therefore, the embodiment of FIG. 3 can be realized with a total height h3 which corresponds to the total height h3 of the embodiment of FIG. 2.

The embodiment of FIG. 3 also reveals that due to a central arrangement of the control device 2 with respect to the stacks the connections to the stacks and thus to the memory arrays arranged in the respective stack are short.

Although both in the case of the embodiment of FIG. 2 and in the case of the embodiment of FIG. 3, the upper memory arrays 3 are arranged in a manner offset inwardly with respect to the lower memory arrays 3, it is also possible for the upper memory arrays to be arranged in a manner offset outwardly above the lower memory arrays. In the case of such an embodiment, the bonding wires for connecting the control device to the pads of the individual memory arrays could be situated in the centre, that is to say where the control device is arranged.

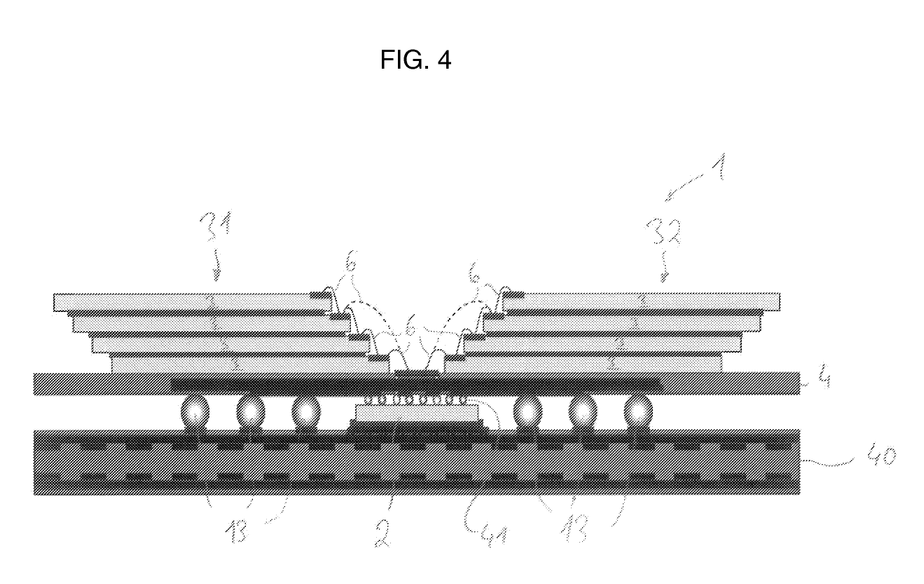

FIG. 4 illustrates a further embodiment of a memory arrangement 1. As with the embodiment of FIG. 2 the memory arrays 3 are arranged in a left-hand stack 31 and a right-hand stack 32. In this embodiment the memory arrays 3 are stacked outwardly, i.e. the part of the upper surface of a memory array 3 which is not covered by the next higher memory array 3 is located in the middle of the printed circuit board. This applies to the left-hand stack 31 and the right-hand stack 32 as well. The bonding wires 6 and the pads are arranged in the middle of the memory arrangement 1, i.e. between the two stacks 31 and 32. This arrangement of the memory arrays 3 can also be implemented in an embodiment using four or more stacks.

While not illustrated in the figures, the memory arrays 3 within the stacks can be orientated in the same direction. In the embodiments illustrated the memory arrays 3 are orientated in the same direction, e.g., in FIG. 4 the memory arrays 3 in the left-hand stack 31 are shifted to the left while the memory arrays 3 in the right-hand stack 32 are shifted to the right. In an embodiment both (or all of the) stacks are shifted to one side.

A further feature of the embodiment illustrated in FIG. 4 is that the control device 2 is arranged on another side of the printed circuit board 4 than the memory arrays 3. Here, the stacks 31 and 32 having the memory arrays 3 are arranged on an upper side of the printed circuit board 4 and the control device 2 is arranged on an opposite lower side of the printed circuit board 4.

The control device 2 is connected to the printed circuit board 4 via contacts 41, e.g., using solder balls or other technologies. The control device 2 is further connected to a further printed circuit board 40, for example, via a module circuit board of a memory module. In this configuration part of the signals and/or supply voltages to and from the memory arrays 3 are routed via the control circuit 2 and the other part is routed via the contacts 13.

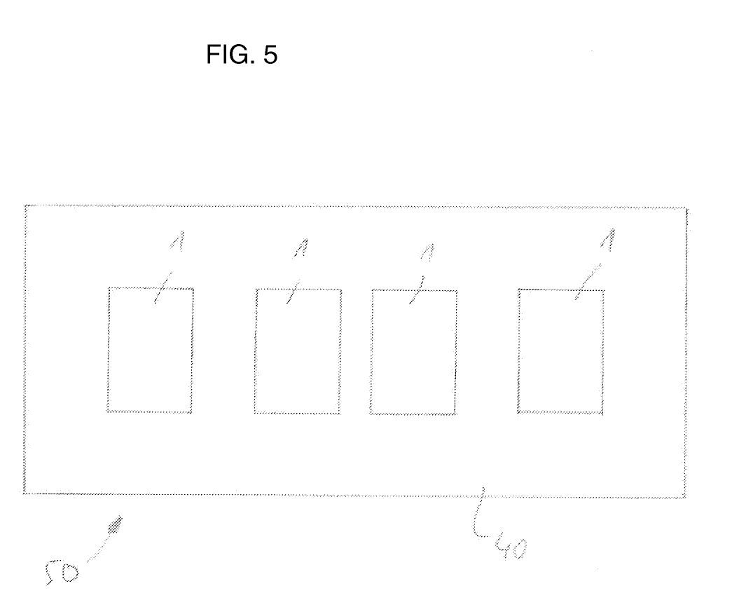

FIG. 5 illustrates a memory module 50 having a module circuit board 40 on which several memory arrangements 1 are attached. The illustration of the memory module 50 is schematic. The size, ratios, the number and configuration of the memory arrangements 1 are just for illustration. The memory arrangements 1 can be employed in every type of memory module, like for example DIMMs, RIMMs, SO-DIMMs or FB-DIMMs having a buffer chip.

The memory arrangements 1 on one module 50 can be of different types from the ones described herein.

The embodiments may be used for producing a DRAM memory arrangement in which more bits can be stored per unit volume. However, no restriction to these embodiments is intended, but rather arrangements including memory types like flash or ROM are encompassed.

The memory arrangement can be utilized in various electronic devices like, e.g., memory sticks, MP3 players and mobile radio devices.

The memory arrangement can further be used as a hard disk. In this embodiment an interface logic device that supports e.g., Serial ATA protocol can be used to serve as an extremely fast hard disk. With the external SATA definition it can be used similar to an USB stick but without the overhead to emulate a hard disk interface by the USB interface.

Such a hard disk could use a battery and circuitry for charging the battery while being connected to a computer or other electronic device. As soon as it is disconnected, the interface chip can set the memory arrays in a self refresh mode. This allows several weeks of data storage using techniques as implemented in mobile ram (e.g., temperature controlled self refresh) or with small batteries.

Embodiments of memory arrangements can also be used in a re-drive environment. Re-drive of data means, that the signalling is based on point to point connections which allow the highest possible speed on the interface. In such an environment several memory arrangements can be used in series instead of the parallel approach of DDR.

This re-drive adds some overhead to the interface logic. Since the interface is separated from the memory arrays the overhead of the re-drive is contained. For example, for an array stack with 4 Gb overall density (4×1 Gb) just one interface chip with re-drive is needed. But for conventional technology this overhead would be needed 4 times.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory arrangement comprising:
a plurality of memory arrays for storing data; and
a control device configured to control the transfer of data between the plurality of memory arrays and external circuits;
wherein the control device is arranged on a different semiconductor chip than the plurality of memory arrays; and
wherein the plurality of memory arrays is arranged symmetrically in a plurality of stacks and the control device is arranged in a central arrangement with respect to the stacks.

2. The memory arrangement according to claim 1, wherein the control device comprises a first interface connectable to the external circuits and a second interface connected to the plurality of memory arrays.

3. The memory arrangement according to claim 2, comprising wherein the control device is configured to serialize data received via the second interface and outputs serialized data via the first interface, and parallelize data received via the first interface and outputs parallelized data via the second interface.

4. The memory arrangement according to claim 1, comprising wherein the plurality of memory arrays is arranged on a first side of a printed circuit board and the control device is arranged on a second side of the printed circuit board.

5. The memory arrangement according to claim 1, comprising wherein the plurality of memory arrays is arranged in two stacks next to each other.

6. The memory arrangement according to claim 1, comprising wherein the plurality of memory arrays is arranged in four stacks which are arranged generally in a rectangular manner.

7. The memory arrangement according to claim 1, comprising wherein memory arrays are arranged one above another by die stacking.

8. The memory arrangement according to claim 2, comprising:
a printed circuit board, wherein the control device is contact-connected to the printed circuit board by flip-chip technology; and
the second interface comprises conductor tracks of the printed circuit board, bonding pads of the printed circuit board which are connected to the conductor tracks, and bonding wires which connect the bonding pads to pads of the memory arrays.

9. The memory arrangement according to claim 1, comprising wherein the control device operates with a clock rate that is at least a factor of 2 higher than a clock rate of the plurality of memory arrays.

10. The memory arrangement according to claim 1, wherein the memory arrangement comprises a DRAM.

11. The memory arrangement according to claim 1, wherein the control device comprises:
at least one device from a set consisting of an address logic of the memory arrangement;
a command decoding device of the memory arrangement;
a refresh logic of the memory arrangement;
a buffering logic; and
a supply voltage generating device of the memory arrangement.

12. The memory arrangement according to claim 2, wherein the first interface comprises at least one device from a set consisting of an output driver, an ESD protection device and a command decoding device.

13. The memory arrangement according to claim 1, wherein the plurality of memory arrays comprises at least one device from a set consisting of a word line and a bit line, an address decoding, a sense amplifier and an address selection.

14. A memory arrangement comprising:
a plurality of memory arrays for storing data;
a control device arranged on a different semiconductor chip than the plurality of memory arrays;
a printed circuit board supporting the control device and the plurality of memory arrays; and
wherein a bottommost memory array of a first stack of memory arrays is arranged on one side of the control device and a bottommost memory array of a second stack of memory arrays is arranged on an opposite side of the control device on the printed circuit board.

15. The memory arrangement according to claim 14, comprising wherein first bonding pads of the printed circuit board are arranged along a side of the first stack and second bonding pads are arranged opposite thereto along a side of the second stack.

16. The memory arrangement according to claim 15, comprising wherein all the memory arrays of the first stack are connected to the first bonding pads via pads of the memory arrays and bonding wires and all the memory arrays of the second stack are connected to the second bonding pads via pads of the memory arrays and bonding wires.

17. The memory arrangement according to claim 15, comprising wherein a connection between the control device and one of the memory arrays comprises by the control device being connected to a pad of a further one of the memory arrays by a first bonding wire and the pad being connected to a pad of the memory array by a second bonding wire.

18. The memory arrangement according to claim 14, comprising wherein the plurality of memory arrays is arranged on a first side of a printed circuit board and the control device is arranged on a second side of the printed circuit board.

19. A memory module comprising:
a module circuit board; and
at least one memory chip arranged on the module circuit board;
wherein the memory chip comprises:
a plurality of memory arrays for storing data; a control device for controlling the transfer of data between the plurality of memory arrays and external circuits;
wherein the control device is arranged on a different semiconductor chip than the plurality of memory arrays; and
wherein the plurality of memory arrays is arranged symmetrically in a plurality of stacks and the control device is arranged in a central arrangement with respect to the stacks.

20. The memory module according to claim 19, comprising wherein the plurality of memory arrays is arranged on a first side of a printed circuit board of the memory chip and the control device is arranged on a second side of the printed circuit board.

21. The memory module according to claim 20, comprising wherein the control device is connected to the printed circuit board of the memory chip and to the module circuit board.

22. An electronic device comprising:
a memory arrangement having
a plurality of memory arrays for storing data; and
a control device for controlling the transfer of data between the plurality of memory arrays and external circuits;
wherein the control device is arranged on a different semiconductor chip than the plurality of memory arrays; and
wherein the plurality of memory arrays is arranged symmetrically in a plurality of stacks and the control device is arranged in a central arrangement with respect to the stacks.

23. A memory arrangement comprising:
a plurality of memory arrays for storing data; and
means for providing a control device configured to control the transfer of data between the plurality of memory arrays and external circuits;
wherein the control device means is arranged on a different semiconductor chip than the plurality of memory arrays; and
wherein the plurality of memory arrays is arranged symmetrically in a plurality of stacks and the control device means is arranged in a central arrangement with respect to the stacks.
